(19) United States
(12) Patent Application Publication
(10) Pub. No.: US 2008/0158986 A1
(43) Pub. Date: Jul. 3, 2008

(54) FLASH MEMORY AND ASSOCIATED METHODS

(76) Inventors: Daniel Elmhurst, Folsom, CA (US); Giovanni Santin, Rieti (IT); Michele Incarnati, Gioia dei Marsi (AQ) (IT); Violante Moschiano, Bacoli (NA) (IT); Ercole Diiorio, Scurcola Marsicana (IT)

Correspondence Address: SCHWEGMAN, LUNDBERG & WOESSNER, P.A., P.O. BOX 2938, MINNEAPOLIS, MN, 55402, US

(21) Appl. No.: 11/618,652

(22) Filed: Dec. 29, 2006

(51) Int. Cl. G11C 16/28

(52) U.S. Cl. 365/185.21

(57) ABSTRACT

In a method of operation, a flash memory cell is programmed, a word-line voltage is coupled to the flash memory cell, and a state of the flash memory cell is sensed at intervals to generate data to indicate a state of the flash memory cell. In a method of operation, a latch in a cache memory of a NAND flash memory is switched off, and the latch is initialized while the latch is switched off. A read voltage is coupled to a gate of a selected flash memory cell in the NAND flash memory where the selected flash memory cell is coupled to a bit-line, and the bit-line is coupled to an input of the latch while a voltage on the bit-line is changing.

### TECHNICAL FIELD

The subject matter relates generally to non-volatile memory devices, and more particularly, to reading and writing data in flash memory devices.

### BACKGROUND

Non-volatile memory devices are becoming more and more popular in consumer electronics. An example of a non-volatile memory device is a flash memory device that stores information in a semiconductor device without the need for power to maintain the information.

There is a need for improved methods of reading and writing data in flash memory devices.

### BRIEF DESCRIPTION OF THE DRAWINGS

FIG. 1 illustrates a block diagram of a memory system according to various embodiments.

FIG. 2 illustrates an electrical schematic diagram of a memory circuit according to various embodiments.

FIG. 3 illustrates a timing diagram for a programming verify operation according to various embodiments.

FIGS. 4A and 4B illustrate voltages for a programming verify operation according to various embodiments.

FIG. 5 illustrates a timing diagram for a read operation according to various embodiments.

FIG. 6 illustrates an electrical schematic diagram of a memory circuit according to various embodiments.

FIG. 7 illustrates a timing diagram for a read operation according to various embodiments.

FIG. 8 illustrates a flow diagram of several methods according to various embodiments.

FIG. 9 illustrates a flow diagram of several methods according to various embodiments.

FIG. 10 illustrates a block diagram of a mobile data processing machine according to various embodiments.

FIG. 11 illustrates a block diagram of a memory component according to various embodiments.

### DETAILED DESCRIPTION

The embodiments described herein are merely illustrative. Therefore, the embodiments shown should not be considered as limiting of the claims.

According to various embodiments, the term pulse refers to the application of a selected voltage level to a terminal for a finite time period. Those skilled in the art will understand that a single pulse may be applied continuously for the finite time period, or may include a series of shorter discrete pulses applied in sequence and having a summed or total time period equal to the finite time period.

According to various embodiments, each transistor or floating gate transistor memory cell is described as being activated or switched on when it is rendered conductive by a voltage on its gate that exceeds its threshold voltage Vₜ, and the transistor or floating gate transistor memory cell is described as being in an inactive state or switched off when the voltage on its gate is below the threshold voltage Vₜ and the transistor or floating gate transistor memory cell is non-conductive.

According to various embodiments, a voltage is evaluated by comparing it with a reference voltage. According to various embodiments, a voltage is evaluated by coupling the voltage to an input of an inverter to compare the voltage with a threshold voltage of the inverter. The inverter may be in a latch circuit. A state of an output of the inverter may change depending on the voltage at its input and its threshold voltage.

All timing diagrams illustrated and described herein show voltages or signals v versus time t.

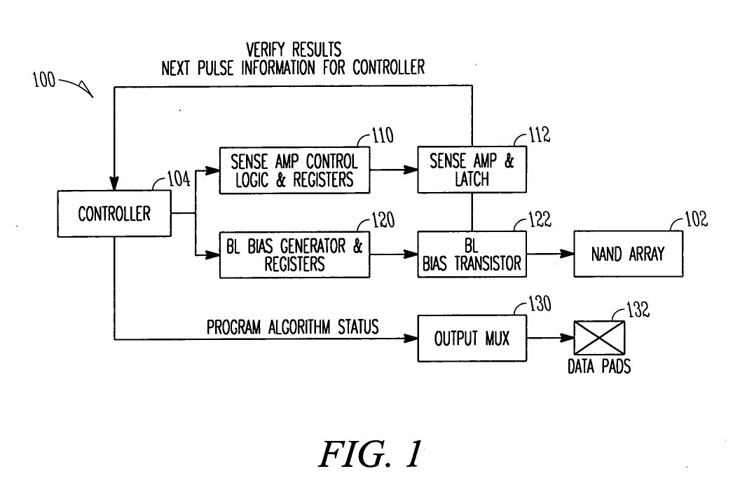

FIG. 1 illustrates a block diagram of a memory system 100 according to various embodiments. The memory system 100 may be called an article. The memory system 100 includes an array 102 of electrically erasable and programmable read only memory devices (EEPROM). The EEPROMs in the array 102 are also called flash memory cells or floating gate transistor memory cells. The floating gate transistor memory cells may have one of two threshold voltages Vₜ, or may be multi-state cells holding one of four or more threshold voltages Vₜ. The memory system 100 also includes a controller 104. The controller 104 is coupled to provide instructions to sense amplifier control logic and registers 110 which in turn is coupled to provide control signals to a sense amplifier and latch 112. The controller 104 is also coupled to provide instructions to a bit-line bias generator and registers 120 which is in turn coupled to provide a control signal to a bit-line bias transistor 122. The sense amplifier and latch 112 and the bit-line bias transistor 122 are both coupled to the array 102 to sense and latch data from flash memory cells in the array 102. The sense amplifier and latch 112 and the bit-line bias transistor 122 may also be referred to as a cache memory for the memory system 100 since they perform the function of cache memory. Data latched from the array 102 in the sense amplifier and latch 112 is coupled to the controller 104. The controller 104 processes data from the sense amplifier and latch 112 and couples the data to an output multiplexer 130, which in turn couples the data to data pads 132.

The controller 104 is a machine and may be a processor, a microprocessor, a state machine, or an application-specific integrated circuit that is a computer-readable medium, or is coupled to a computer-readable medium or a machine-accessible medium such as a memory, in a computer-based system to execute functions and methods according to various embodiments described herein. The memory may be the array 102 or may include electrical, optical, or electromagnetic elements. The computer-readable medium or a machine-accessible medium may contain associated information such as computer program instructions, data, or both which, when accessed, results in a machine performing the activities described herein.

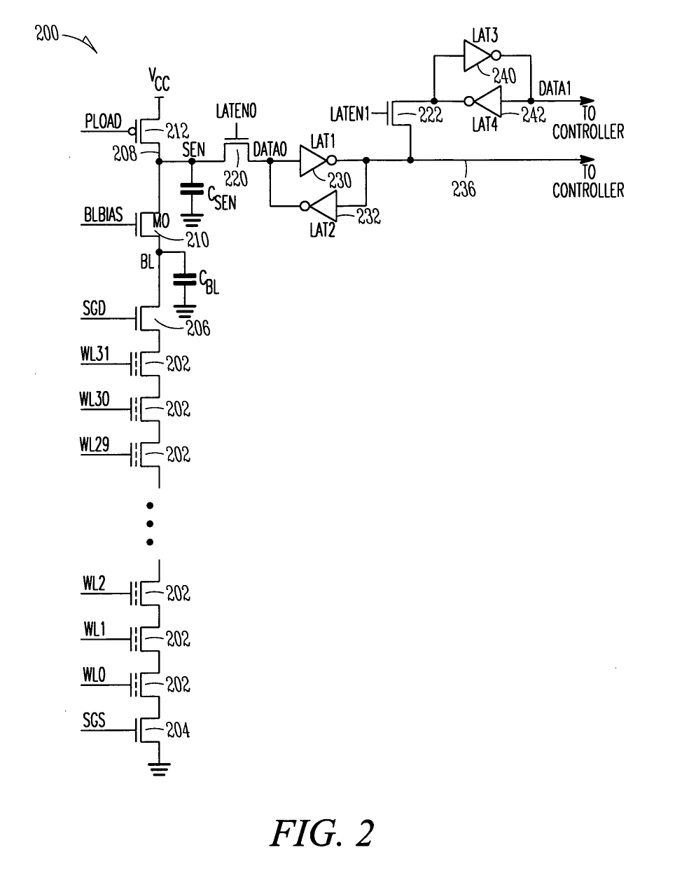

FIG. 2 illustrates an electrical schematic diagram of a memory circuit 200 according to various embodiments. Illustrated in FIG. 2 is a nandstring of flash memory cells or floating gate transistor memory cells 202. There are 32 flash memory cells 202 in the nandstring, numbered 0 to 31. The nandstring of flash memory cells 202 is located in the array 102 with other nandstrings of flash memory cells. Each flash memory cell 202 is controlled by a respective one of 32 word-line signals WL0 to WL31 coupled to its gate terminal.

Each flash memory cell 202 includes a source, a drain, a floating gate and a control gate. The flash memory cells 202 are coupled drain to source in each nandstring. The nandstring includes a source select transistor 204, an n-channel transistor coupled between a source of the first flash memory cell 202 and a ground voltage reference. At the other end of the nandstring, a drain select transistor 206 is an n-channel transistor coupled between a drain of the last flash memory cell 202 and the rest of the memory circuit 200. The drain select transistor 206 is coupled in series between the nandstring and a bit-line 208 with a bias transistor MO 210 and a load transistor 212. The bit-line 208 has a voltage BL and a capacitance C_{BL}. The bias transistor 210 is an n-channel transistor having a source coupled to the drain select transistor 206 and a drain. The load transistor 212 is a p-channel transistor having a drain coupled to the drain of the bias transistor 210 and a source coupled to a voltage supply Vcc. A source select control signal SGS is coupled to a control gate of the source select transistor 204, and a drain select control signal SGD is coupled to a control gate of the drain select transistor 206. A control signal BLBIAS is coupled to a control gate of the bias transistor 210, and a control signal PLOAD is coupled to a control gate of the load transistor 212. The bias transistor 210 is one of multiple bias transistors 122 in the memory system 100 shown in FIG. 1.

The bit-line 208 is coupled to the sense amplifier and latch 112 of the memory system 100 between the bias transistor 210 and the load transistor 212. The sense amplifier and latch 112 includes multiple latch transistors and inverters, one set of which is illustrated in FIG. 2 for latching data from the flash memory cells 202. A first latch transistor 220 and a second latch transistor 222 control data transfer from the nandstring. The first and second latch transistors 220, 222 are n-channel transistors, each having a control gate coupled to a respective control signal LATEN0 and LATEN1. A coupling between the first latch transistor 220 and the bit-line 208 has a voltage SEN and a capacitance C_{SEN} that is much smaller than C_{BL}. The voltage SEN driven by the capacitance C_{SEN} is unlatched data from the nandstring and will be further described hereinbelow. A first latch includes a first inverter 230 and a second inverter 232. The first inverter 230 has an input coupled to a source of the first latch transistor 220 and an output coupled to an input of the second inverter 232. An output of the second inverter 232 is coupled to the input of the first inverter 230 and the source of the first latch transistor 220. A drain of the first latch transistor 220 is coupled to the bit-line 208 and the voltage SEN. The input of the second inverter 232 and the output of the first inverter 230 are coupled to a data line 236 that is coupled to the controller 104 shown in FIG. 1.

A second latch including a third inverter 240 and a fourth inverter 242 is coupled through the second latch transistor 222 to the data line 236. An input of the third inverter 240 and an output of the fourth inverter 242 are coupled to a source of the second latch transistor 222, and a drain of the second latch transistor 222 is coupled to the data line 236. An output of the third inverter 240 and an input of the fourth inverter 242 are coupled to a second data line 246 that is coupled to the controller 104 shown in FIG. 1.

Each of the flash memory cells 202 is programmed according to various embodiments by coupling a program pulse to its gate to induce charge to be drawn to the floating gate to raise the threshold voltage Vₜ of the flash memory cell 202. Early in the programming, strong program pulses are applied to the gate resulting in a large change in the threshold voltage Vₜ. As the threshold voltage Vₜ of the flash memory cell 202 approaches a target, weaker program pulses are applied to the gate resulting in smaller changes in the threshold voltage Vₜ. After each program pulse, the threshold voltage Vₜ is verified twice before another program pulse is applied.

A selected flash memory cell 202 is read according to various embodiments by coupling a read voltage to its gate (WL0 to WL31), rendering the source select transistor 204 and the drain select transistor 206 conductive and switching on all the other floating gate cells 202 in the nandstring such that they are also conductive. The bias transistor 210 and the load transistor 212 are switched on such that the bit-line 208 is charged from the voltage Vcc. The load transistor 212 is then switched off and charge on the bit-line 208 will flow through the selected flash memory cell 202 if it is not programmed, such that the voltage BL on the bit-line 208 decreases once the load transistor 212 is switched off. However, if the selected flash memory cell has been programmed, then charge on the bit-line 208 will not be lost through the nandstring. The first and second latches including the inverters 230, 232, 240, and 242, and the first and second latch transistors 220 and 222 are capable of latching data from the bit-line 208 as will be described.

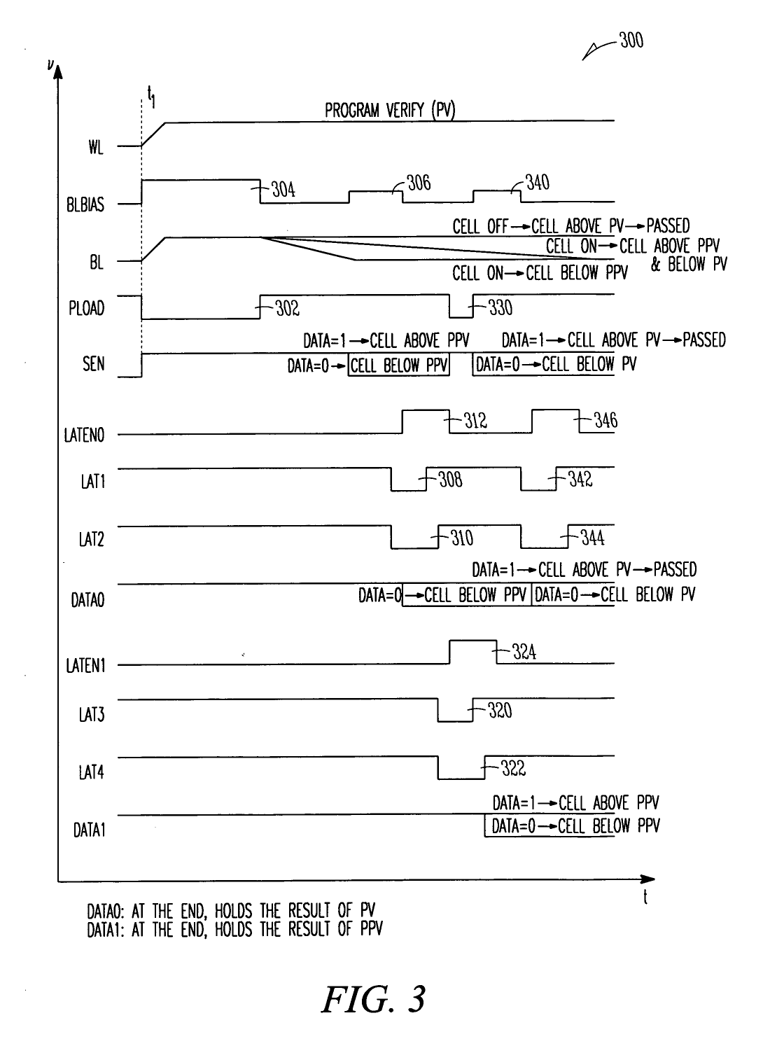

FIG. 3 illustrates a timing diagram 300 for a programming verify operation according to various embodiments. FIG. 3 illustrates a signal WL coupled to a gate of a selected flash memory cell 202 being programmed. The programming verify operation takes place after the selected flash memory cell 202 receives a programming pulse. Also illustrated are a signal BLBIAS coupled to the gate of the bias transistor 210; a voltage BL of the bit-line 208; a signal PLOAD coupled to a gate of the load transistor 212, and a voltage SEN at a node between the load transistor 212 and the bias transistor 210. The signals LATEN0 and LATEN1 are coupled, respectively, to gates of the first and second latch transistors 220, 222 to switch the first and second latch transistors 220, 222 on and off. The signals LAT1, LAT2, LAT3, and LAT4 are coupled, respectively to switch on and off the inverters 230, 232, 240, and 242. The signals DATA0 and DATA1 indicate digital data latched by the respective pairs of inverters 230, 232 and 240, 242 to indicate a state of the selected flash memory cell 202.

At time t₁ in FIG. 3, the signal BLBIAS rises to a voltage Vclamp and the signal PLOAD goes low for significant pulses 302 and 304 to switch on the load transistor 212 and the bias transistor 210, respectively. The bit-line 208 is then coupled to the supply voltage Vcc through the load transistor 212 and the voltage BL on the bit-line 208 rises as the bit-line is charged to a voltage Vclamp less the threshold voltage Vₜ of the bias transistor 210. Also at time t₁, the voltage WL on the gate of the selected flash memory cell 202 rises to a program verify PV level.

At the end of the pulses 302, 304, the bias transistor 210 and the load transistor 212 are switched off, and the voltage BL on the bit-line 208 remains the same or falls depending on the state of the selected flash memory cell 202. If the threshold voltage Vₜ of the cell 202 is below a pre-program verify PPV level, the cell 202 will be rendered conductive and the bit-line 208 will discharge quickly. If the threshold voltage Vₜ of the cell 202 is above PPV and below PV, the cell 202 will be rendered conductive and the bit-line 208 will discharge at a more gradual slope. If the threshold voltage Vₜ of the cell 202 is above PV, the cell 202 will not be conductive and the bit-line 208 will hold its charge, remaining at a high voltage BL. The discharge of the bit-line 208 is influenced by its capacitance C_{BL}.

The programming verify operation now proceeds to latch DATA0 and DATA1 across an interval to determine if the bit-line 208 is being discharged, and if so, what the rate of the discharge is. DATA1 is captured in the following manner. The signal BLBIAS rises to a voltage less than Vclamp for a short pulse 306 to switch on the bias transistor 210 to allow the voltage SEN to settle to the voltage BL of the bit-line 208. The voltage SEN is captured by the capacitance C_{SEN} between the bias transistor 210 and the load transistor 212. The capacitance C_{SEN} is much less than the capacitance C_{BL} of the bit-line 208. The signals LAT1 and LAT2 go low for short pulses 308, 310 to switch off the inverters 230, 232, then the BLBIAS pulse 306 ends to switch off the bias transistor 210 and the first latch transistor 220 is switched on by a pulse 312 of the signal LATEN0 to allow the voltage SEN to transfer from the capacitance C_{SEN} to the input of the inverter 230. The inverters 230, 232 are switched off to avoid disturbing the transfer and are switched on in sequence at the end of the pulses 308, 310 to latch DATA0. DATA0 is low if the threshold voltage Vₜ of the cell 202 is below PPV, and is high otherwise.

DATA0 is then transferred to DATA1 in the following manner. At the end of pulse 310 the inverter 232 is switched on and the signals LAT3 and LAT4 go low for short pulses 320, 322 to switch off the inverters 240, 242. The first latch transistor 220 is switched off at the end of the pulse 312 when DATA0 is latched, and the second latch transistor 222 is switched on by a pulse 324 of the signal LATEN1 to allow the inverted DATA0 to transfer from the output of the inverter 230 to the input of the inverter 240. The inverters 240, 242 are switched off to avoid disturbing the transfer, and are switched on in sequence at the end of the pulses 320, 322 to latch DATA1. DATA1 at the output of the inverter 240 is the same as the previously latched DATA0 at the input of the inverter 230. The second latch transistor 222 is switched off at the end of pulse 324 after DATA1 has been latched. DATA1 is low if the threshold voltage Vₜ of the cell 202 is below PPV, and DATA1 is high if the threshold voltage Vₜ of the cell 202 is above PPV.

At the end of pulse 312 when the first latch transistor 220 is switched off, the signal PLOAD goes low for a short pulse 330 to switch on the load transistor 212 to raise the SEN voltage between the load transistor 212 and the bias transistor 210. The capacitance C_{SEN} rises to a high voltage during the pulse 330, but the bit-line 208 below the bias transistor 210 is unaffected and the voltage BL continues its trend.

At the end of the pulse 330, the signal BLBIAS rises to a voltage less than Vclamp for a short pulse 340 to switch on the bias transistor 210 to allow the voltage SEN to settle to the voltage BL of the bit-line 208. The signals LAT1 and LAT2 go low again for short pulses 340, 342 to switch off the inverters 230, 232, then the BLBIAS pulse 340 ends to switch off the bias transistor 210 and the first latch transistor 220 is switched on by a pulse 346 of the signal LATEN0 to allow the voltage SEN to transfer from the capacitance C_{SEN} to the input of the inverter 230. The inverters 230, 232 are switched on in sequence at the end of the pulses 342, 344 to latch a new DATA0 that is possibly different from the first latched DATA0. The first latch transistor 220 is switched off at the end of pulse 346. DATA0 is low if the threshold voltage Vₜ of the cell 202 is below PV, and DATA0 is high if the threshold voltage Vₜ of the cell 202 is above PV.

In this manner the bit-line 208 is strobed twice to obtain two data points DATA0 and DATA1 separated by an interval while the same signal WL at the PV voltage is coupled to the gate of a selected flash memory cell 202 being programmed. According to various embodiments, the bit-line 208 is strobed three or more times to obtain three or more data points separated by intervals while the same signal WL at the PV voltage is coupled to the gate of a selected flash memory cell 202 being programmed.

The selected flash memory cell 202 may be read according to the timing diagram 300 according to various embodiments. The signal WL rises to a read voltage, and the bit-line 208 is strobed two or more times to obtain two or more data points representing two or more threshold voltages Vₜ of the cell 202 separated by intervals. The data points may be coupled directly to the data line 236 and the controller 104 shown in FIG. 1 without a need for more than one latch.

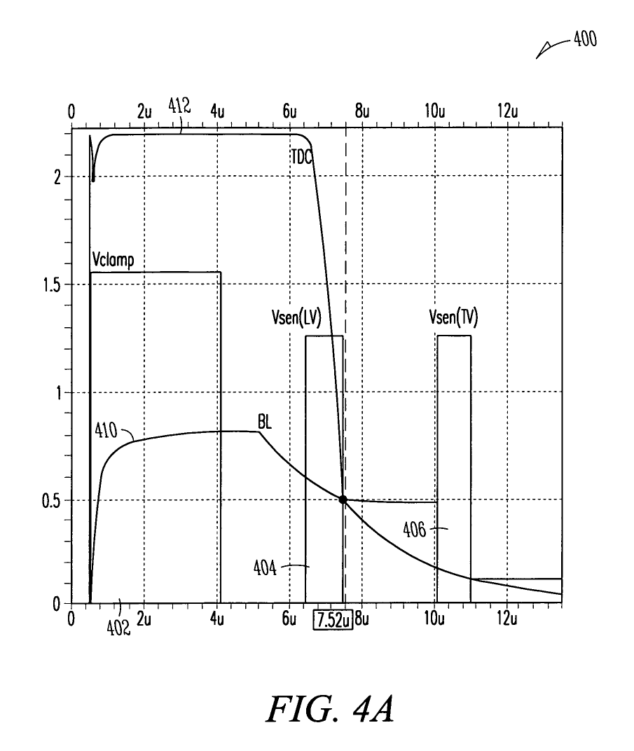

FIGS. 4A and 4B illustrate voltages for a programming verify operation according to various embodiments. FIG. 4A illustrates voltages 400 for a programming verify operation of a selected flash memory cell that has a threshold voltage Vₜ below PPV. Illustrated are three pulses 402, 404, and 406 of the signal BLBIAS. The pulse 402 is at the voltage Vclamp, and the short pulses 404, 406 of the signal BLBIAS switch on the bias transistor 210 to allow the voltage SEN to settle to the voltage BL of the bit-line 208. Also illustrated in FIG. 4A is the voltage BL 410 and the voltage SEN 412. FIG. 4B illustrates voltages 450 for a programming verify operation of a selected flash memory cell that has a threshold voltage Vₜ above PPV and below PV. Illustrated are three pulses 452, 454, and 456 of the signal BLBIAS. The pulse 452 is at the voltage Vclamp, and the short pulses 454, 456 of the signal BLBIAS switch on the bias transistor 210 to allow the voltage SEN to settle to the voltage BL of the bit-line 208. Also illustrated in FIG. 4B is the voltage BL 460 and the voltage SEN 462.

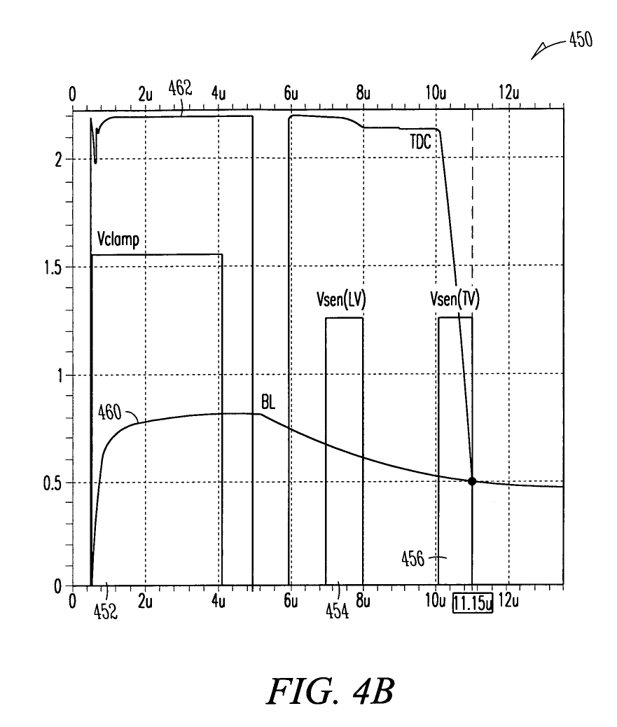

FIG. 5 illustrates a timing diagram 500 for a read operation according to various embodiments. FIG. 5 illustrates a signal WL coupled to a gate of a selected flash memory cell 202 being read. Also illustrated are a signal BLBIAS coupled to the gate of the bias transistor 210; a voltage BL of the bit-line 208; a signal PLOAD coupled to a gate of the load transistor 212, and a voltage SEN at a node between the load transistor 212 and the bias transistor 210. The signals LATEN0 and LATEN1 are coupled, respectively, to gates of the first and second latch transistors 220, 222 to switch the first and second latch transistors 220, 222 on and off. The signals LAT1 and LAT2 are coupled, respectively to switch on and off the inverters 230 and 232. The signal DATA0 indicates digital data latched by the pair of inverters 230, 232 to indicate a state of the selected flash memory cell 202.

At time t₁ in FIG. 5, the signal BLBIAS rises to a voltage Vclamp and the signal PLOAD goes low for significant pulses 502 and 504 to switch on the load transistor 212 and the bias transistor 210, respectively. The bit-line 208 is then coupled to the supply voltage Vcc through the load transistor 212 and the voltage BL on the bit-line 208 rises as the bit-line is charged to a voltage Vclamp less the threshold voltage Vₜ of the bias transistor 210. Also at time t₁, the voltage WL on the gate of the selected flash memory cell 202 rises to a read voltage.

At the end of the pulses 502, 504, the bias transistor 210 and the load transistor 212 are switched off, and the voltage BL on the bit-line 208 remains the same or falls depending on the state of the selected flash memory cell 202. If the threshold voltage Vₜ of the cell 202 is far below the read voltage, the cell 202 will be rendered conductive and the bit-line 208 will discharge quickly. If the threshold voltage Vₜ of the cell 202 is just below the read level, the cell 202 will be rendered conductive and the bit-line 208 will discharge at a more gradual slope. If the threshold voltage Vₜ of the cell 202 is above the read voltage, the cell 202 will not be conductive and the bit-line 208 will hold its charge, remaining at a high voltage BL.

The signal BLBIAS rises to a voltage less than Vclamp for a short pulse 506 to switch on the bias transistor 210 to allow the voltage SEN to settle to the voltage BL of the bit-line 208. However, data is not latched during or after the pulse 506, but the pulse 506 is applied to mirror the pulse 306 described with respect to the programming verify operation illustrated in FIG. 3. The pulse 506 may be called a dummy BL strobe. The bit-line 208 is subject to the same signal BLBIAS during both the read operation and the programming verify operation such that the results of the two operations are the same. The application of the pulse 506 reduces the likelihood that data resulting from a read operation for the cell 202 will be different from data resulting from a programming verify operation for the cell 202.

Following the pulse 506, the signal PLOAD goes low for a short pulse 507 to switch on the load transistor 212 to raise the SEN voltage between the load transistor 212 and the bias transistor 210. The capacitance C_{SEN} rises to a high voltage during the pulse 507, but the bit-line 208 below the bias transistor 210 is unaffected and the voltage BL continues its trend.

The read operation now proceeds to latch DATA0 to determine a state of the selected flash memory cell 202. The signal BLBIAS rises to a voltage less than Vclamp for a short pulse 508 to switch on the bias transistor 210 to allow the voltage SEN to settle to the voltage BL of the bit-line 208. The voltage SEN is captured by the capacitance C_{SEN} between the bias transistor 210 and the load transistor 212. The signals LAT1 and LAT2 go low for short pulses 518, 520 to switch off the inverters 230, 232, then the BLBIAS pulse 508 ends to switch off the bias transistor 210 and the first latch transistor 220 is switched on by a pulse 522 of the signal LATEN0 to allow the voltage SEN to transfer from the capacitance C_{SEN} to the input of the inverter 230. The inverters 230, 232 are switched off to avoid disturbing the transfer, and are switched on in sequence at the end of the pulses 518, 520 to latch DATA0. DATA0 is low if the threshold voltage Vₜ of the selected flash memory cell 202 is below the read voltage, and is high if the threshold voltage Vₜ of the selected flash memory cell 202 is above the read voltage. The signal LATEN1 is not active during the read operation because only one data value is latched.

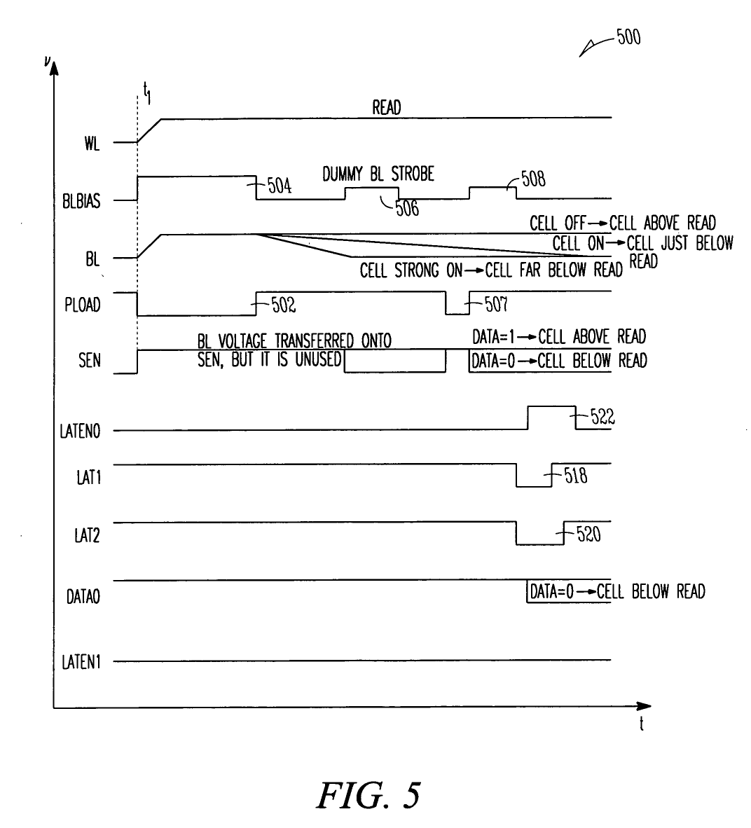

FIG. 6 illustrates an electrical schematic diagram of a memory circuit 600 according to various embodiments. The memory circuit 600 includes many elements in common with the memory circuit 200 shown in FIG. 2, and similar elements, voltages, and signals are given the same reference numbers and letters for purposes of brevity. The elements common to the memory circuits 200 and 600 have the same function, position, and orientation in the respective circuit. The memory circuit 600 also includes an equalization transistor 602, an n-channel transistor having a source coupled to the input of the inverter 230 and a drain coupled to the output of the inverter 230. A control signal EQ is coupled to a gate of the equalization transistor 602. When rendered conductive by the signal EQ, the equalization transistor 602 permits charge transfer between the input and the output of the inverter 230 to reduce a potential difference between them and remove data latched by the inverters 230, 232 to initialize the latch. The bias transistor 210, the first latch transistor 220, and the inverters 230 and 232 are included in the cache memory for the memory circuit 600 as they perform the function of a cache memory.

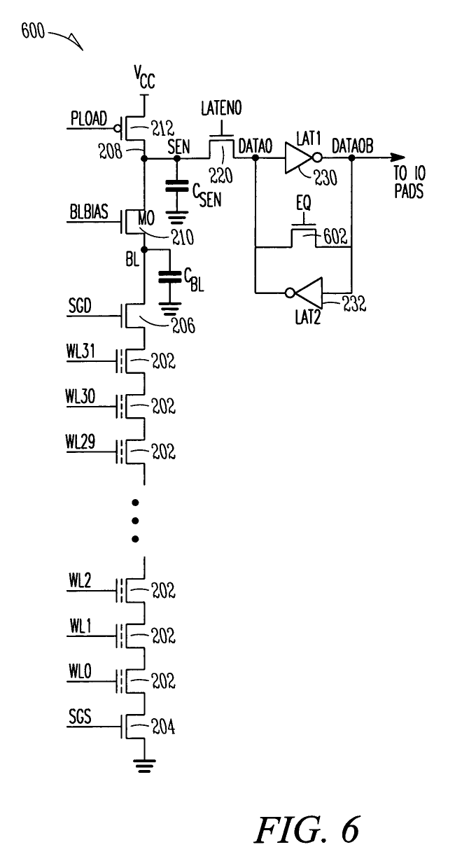

FIG. 7 illustrates a timing diagram 700 for a read operation according to various embodiments. FIG. 7 illustrates a signal BLBIAS coupled to the gate of the bias transistor 210, a voltage BL of the bit-line 208, a voltage SEN at a node between the load transistor 212 and the bias transistor 210, and a signal PLOAD coupled to a gate of the load transistor 212. A signal LATEN0 is coupled to a gate of the first latch transistor 220 to switch the first latch transistor 220 on and off. A signal EQ is coupled to a gate of the equalization transistor 602. The signals LAT1 and LAT2 are the same and are coupled, respectively, to switch on and off the inverters 230 and 232. The signal DATA0 indicates digital data latched by the pair of inverters 230, 232 to indicate a state of the selected flash memory cell 202, and the signal DATA0B is the signal DATA0 inverted.

As the signals begin in the timing diagram 700, the signal BLBIAS rises to a voltage Vclamp and the signal PLOAD goes low for significant pulses 702 and 704 to switch on the load transistor 212 and the bias transistor 210, respectively. The bit-line 208 is then coupled to the supply voltage Vcc through the load transistor 212 and the voltage BL on the bit-line 208 rises as the bit-line is charged to a voltage Vclamp less the threshold voltage Vₜ of the bias transistor 210. A read voltage (not shown) is coupled to a gate of a selected flash memory cell 202.

At the end of the pulses 702, 704 the bias transistor 210 and the load transistor 212 are switched off, and the voltage BL on the bit-line 208 remains the same or falls depending on the state of the selected flash memory cell 202. If the threshold voltage Vₜ of the cell 202 is below the read voltage, the cell 202 will be rendered conductive and the bit-line 208 will discharge. If the threshold voltage Vₜ of the cell 202 is above the read voltage, the cell 202 will not be conductive and the bit-line 208 will hold its charge, remaining at a high voltage BL.

Thereafter, the signal EQ goes high for a short pulse 730 to switch on the equalization transistor 602 to permit charge transfer between the input and the output of the inverter 230 to reduce a potential difference between them and remove data latched by the inverters 230, 232 to initialize the latch. At the same time the signals LAT1 and LAT2 are brought low for a longer pulse 728 to switch off the inverters 230 and 232.

Following the pulse 730 when the latch is initialized and the equalization transistor 602 is switched off, the signal BLBIAS rises to a voltage less than Vclamp for a short pulse 740 to switch on the bias transistor 210 to allow the voltage SEN to settle to the voltage BL of the bit-line 208. The voltage SEN is captured by the capacitance C_{SEN} between the bias transistor 210 and the load transistor 212. At the same time the first latch transistor 220 is switched on by a pulse 750 of the signal LATEN0 to allow the voltage SEN to transfer from the capacitance C_{SEN} to the input of the inverter 230. As a result, the bit-line 208 is coupled to the capacitance C_{SEN} and to the input of the inverter 230 as the voltage BL is developing on the bit-line 208 and possibly discharging if the selected flash memory cell 202 is rendered conductive. The signal DATA0 is coupled directly from the voltage BL on the bit-line 208 during the pulses 728, 740, and 750.

The BLBIAS pulse 740, the LATEN0 pulse 750, and the LAT1/LAT2 pulse 728 all end at the same time to switch off the bias transistor 210 and the first latch transistor 220 and switch on the inverters 230, 232 to latch DATA0. DATA0 is low if the threshold voltage Vₜ of the selected flash memory cell 202 is below the read voltage and is high if the threshold voltage Vₜ of the selected flash memory cell 202 is above the read voltage. The signal DATA0B is the signal DATA0 inverted.

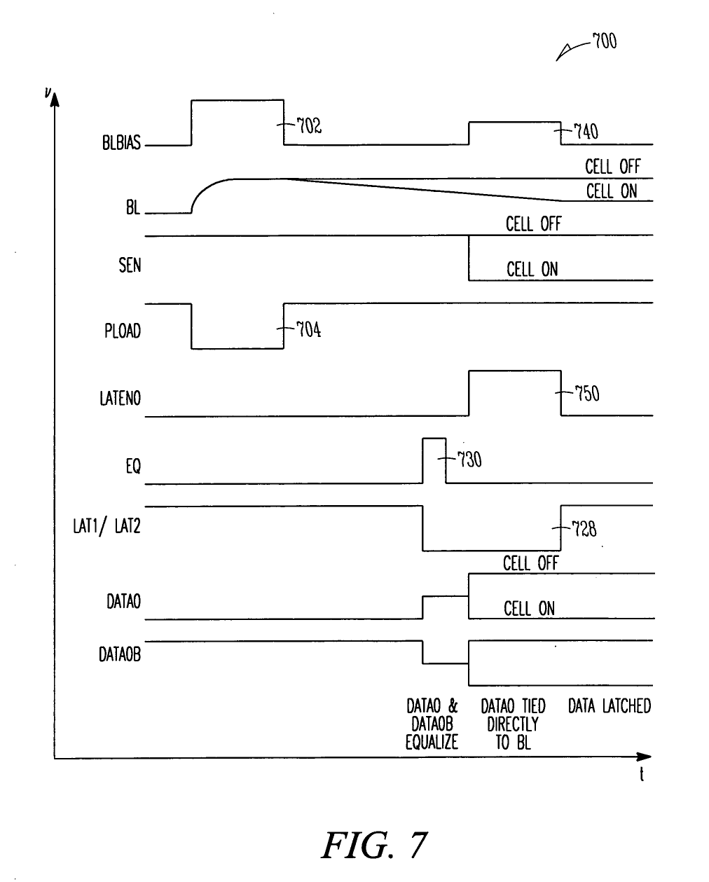

FIG. 8 illustrates a flow diagram of several methods according to various embodiments. In 810, the methods start.

In 820, a flash memory cell is programmed.

In 830, a word-line voltage is applied to the flash memory cell.

In 840, a bit-line coupled to the flash memory cell is coupled to a sense capacitance at a first time to generate first data.

In 850, the bit-line is coupled to the sense capacitance at a second time to generate second data.

In 860, the first data is stored in a latch circuit.

In 870, the second data is stored in a latch circuit

In 880, the flash memory cell is read by applying pulses having the same duration and occurring at the same intervals, respectively, as pulses applied to verify a programming of the flash memory cell such that a bit-line coupled to the flash memory cell is coupled to a sense capacitance during the same intervals when the programming of the flash memory cell is being verified and when the flash cell is being read. In 890, the methods end.

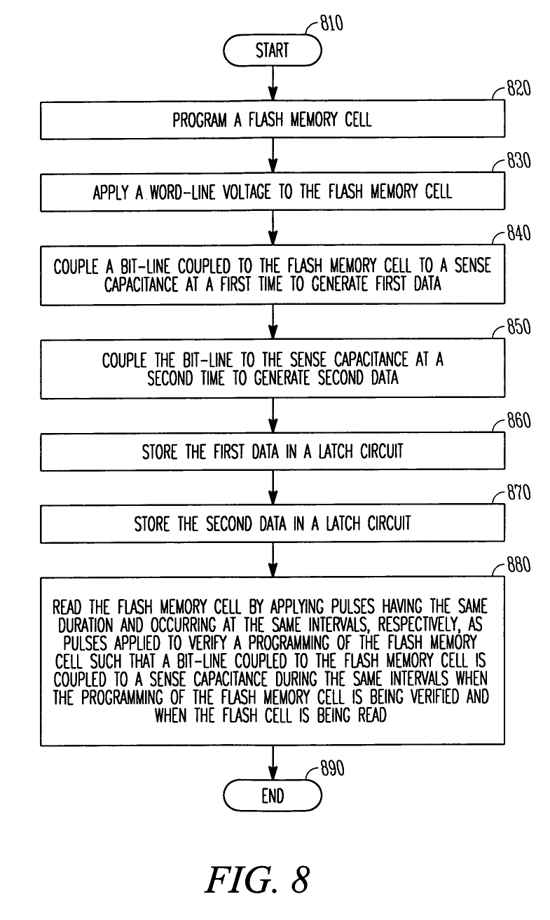

FIG. 9 illustrates a flow diagram of several methods according to various embodiments. In 910, the methods start.

In 920, a latch in a cache memory of a NAND flash memory is switched off.

In 930, the latch is initialized while the latch is switched off.

In 940, a read voltage is coupled to a gate of a selected flash memory cell in the NAND flash memory, the selected flash memory cell being coupled to a bit-line.

In 950, the bit-line is coupled to an input of the latch while a voltage on the bit-line is changing due to the read voltage coupled to the selected flash memory cell and the latch is switched off.

In 960, the latch is switched on to latch data based on the voltage on the bit-line. In 970, the methods end.

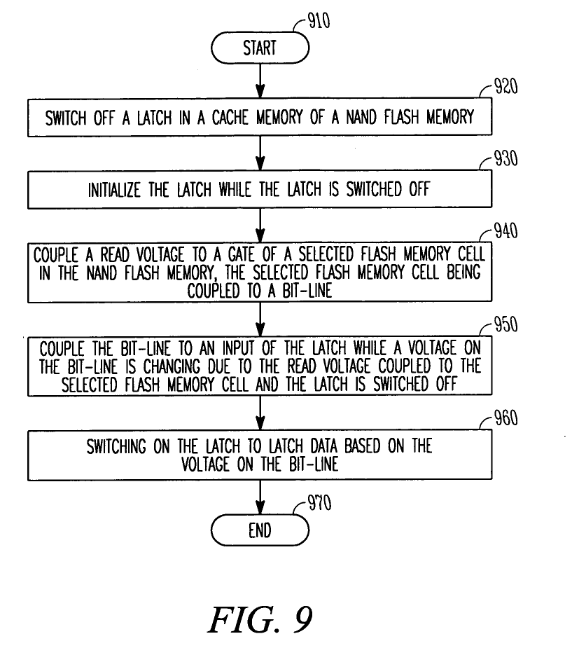

FIG. 10 illustrates a block diagram of a mobile data processing machine 1000 according to various embodiments. The machine 1000 may also be called an article. The machine 1000 includes a central processor 1010 and a non-volatile memory 1020, such as described above. The non-volatile memory 1020 may be an electrically erasable and programmable non-volatile memory, such as an EEPROM. The machine 1000 further includes instructions used to program operational characteristics of the non-volatile memory 1020 in accordance with functions and methods according to various embodiments described herein. The machine 1000 also may include a transceiver 1030 such as a radio transceiver, and an antenna 1040, a display 1050, and/or an input device 1060. The machine 1000 may be a cellular telephone, a personal digital assistant (PDA), a laptop, a digital camera, etc. The non-volatile memory 1020 provides storage of programs and/or data for the machine 1000, including during a powered down state.

The central processor 1010 is a machine and may be a processor, a microprocessor, a state machine, or an application-specific integrated circuit that is a computer-readable medium, or is coupled to a computer-readable medium or a machine-accessible medium such as a memory, in a computer-based system to execute functions and methods according to various embodiments described herein. The memory may be the non-volatile memory 1020 or may include electrical, optical, or electromagnetic elements. The computer-readable medium or a machine-accessible medium may contain associated information such as computer program instructions, data, or both which, when accessed, results in a machine performing the activities described herein.

The machine 1000 is a wireless computing platform according to various embodiments. The machine 1000 may interact with one or more networks such as a WAN (Wireless Area Network), a WLAN (Wireless Local Area Network), and a WPAN (Wireless Personal Area Network). The machine 1000 may be hand-held or larger. The antenna 1040 may comprise a monopole, a dipole, a unidirectional antenna, an omnidirectional antenna, or a patch antenna, among others. A wireless computing platform may be any device capable of conducting wireless communication (e.g., infra-red, radio frequency, etc.) and executing a series of programmed instructions (e.g., a personal digital assistant, a laptop, a cellular telephone, etc.).

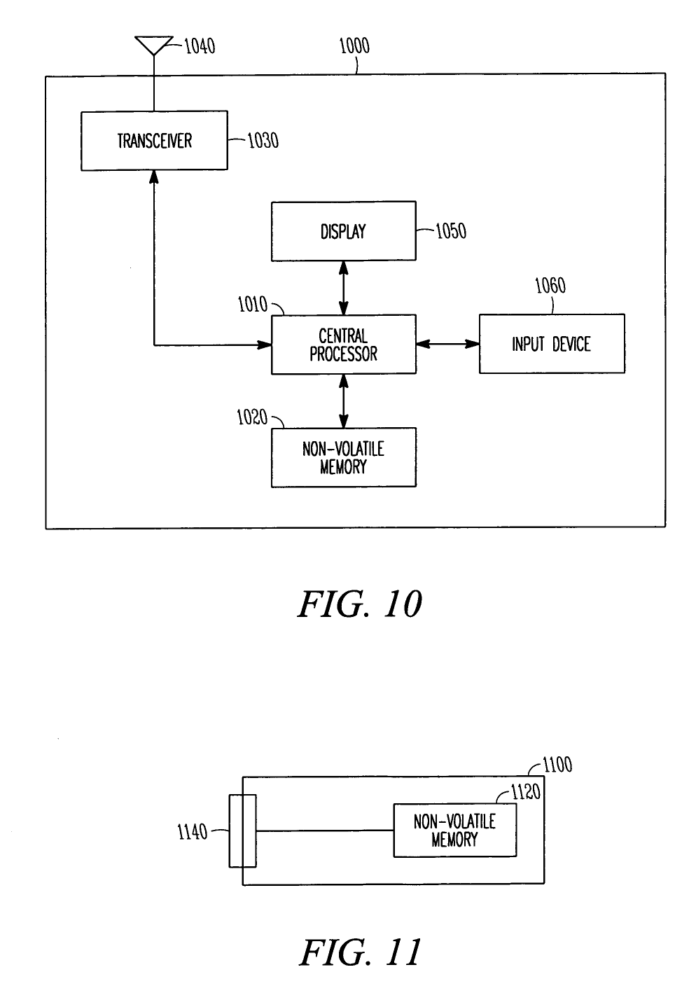

FIG. 11 illustrates a block diagram of a memory component 1100 according to various embodiments. The memory component 1100 may be called an article. The memory component 1100 may be a memory card, a memory chip, a memory stick, etc. The memory component 1100 includes a non-volatile memory 1120, such as describe above, which may be an electrically erasable and programmable non-volatile memory, such as an EEPROM. The memory component 1100 also includes a connector 1140, and may further include instructions used to program operational characteristics of the non-volatile memory 1120 in accordance with functions and methods according to various embodiments described herein. Alternatively, these instructions may be provided when the memory component 1100 is installed in a machine, such as the machines 104 or 1000, using the connector 1140.

The various embodiments illustrated and described herein may be implemented in a NAND flash memory device or other types of memory devices. The various embodiments illustrated and described herein may be implemented with floating gate transistor memory cells that have one of two threshold voltages Vₜ, or with multi-state floating gate transistor memory cells holding one of four or more threshold voltages Vₜ.

Although specific embodiments have been illustrated and described herein, it should be appreciated that any arrangement calculated to achieve the same purpose may be substituted for the specific embodiments shown. This disclosure is intended to cover any and all adaptations or variations of various embodiments. It is to be understood that the above description has been made in an illustrative fashion, and not a restrictive one. Combinations of the above embodiments, and other embodiments not specifically described herein will be apparent to those of skill in the art upon reviewing the above description. Thus, the scope of various embodiments includes any other applications in which the above compositions, structures, and methods are used.

It is emphasized that the Abstract of the Disclosure is provided to comply with 37 C.F.R. § 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate preferred embodiment. In the appended claims, the terms “including” and “in which” may be used as the plain-English equivalents of the respective terms “comprising” and “wherein,” respectively. Moreover, the terms “first,” “second,” and “third,” etc. are used merely as labels, and are not intended to impose numerical requirements on their objects.

1. A method comprising:
programming a flash memory cell;
coupling a word-line voltage to the flash memory cell; and
sensing a state of the flash memory cell at a plurality of intervals to generate a plurality of data to indicate the state of the flash memory cell.

2. The method of claim 1 wherein sensing a state of the flash memory cell includes:
sensing a first voltage on a bit-line to which the flash memory cell is coupled at a first interval; and
sensing a second voltage on the bit-line at a second interval.

3. The method of claim 2, further comprising:
comparing the first voltage with a reference voltage to generate first data;
comparing the second voltage with the reference voltage to generate second data; and
storing the second data in a first latch and storing the first data in a second latch.

4. The method of claim 3 wherein:
comparing the first voltage with a reference voltage includes coupling the first voltage from a sense capacitance through a latch transistor to an input of an inverter in a first latch circuit to compare the first voltage with a threshold voltage of the inverter;
comparing the second voltage with the reference voltage includes coupling the second voltage from the sense capacitance through the latch transistor to the input of the inverter in the first latch circuit to compare the second voltage with the threshold voltage of the inverter; and
storing the second data includes:
storing the second data in the first latch circuit, the first latch circuit including a pair of inverters, each inverter having an output connected to an input of the other inverter to hold the second data; and
storing the first data in a second latch circuit, the second latch circuit including a pair of inverters, each inverter having an output connected to an input of the other inverter to hold the first data.

5. The method of claim 1 wherein sensing a state of the flash memory cell includes strobing a bit-line coupled to the flash memory cell at a plurality of intervals to generate a plurality of data to indicate a state of the flash memory cell.

6. The method of claim 1 wherein sensing a state of the flash memory cell includes:
coupling a bit-line coupled to the flash memory cell to a sense capacitance at a first time to generate first data; and
coupling the bit-line to the sense capacitance at a second time to generate second data.

7. The method of claim 6 wherein sensing a state of the flash memory cell includes:
coupling a first pulse to a bias transistor coupled between the bit-line and the sense capacitance at the first time; and
coupling a second pulse to the bias transistor at the second time.

8. The method of claim 7, further comprising:
coupling a read voltage to the flash memory cell;
coupling a third pulse to the bias transistor at a third time;
coupling a fourth pulse to the bias transistor at a fourth time, the third pulse and the fourth pulse having the same duration and occurring at the same intervals, respectively, as the first pulse and the second pulse such that the bit-line is coupled to the sense capacitance at the same intervals when a programming of the flash memory cell is being verified and when the flash cell is being read; and
latching data from the sense capacitance after the fourth time to read a state of the flash memory cell.

9. The method of claim 6, further comprising:
coupling a pre-program verify voltage to a gate of the flash memory cell at the first time; and
coupling a program verify voltage to the gate of the flash memory cell at the second time, the program verify voltage being greater than the pre-program verify voltage to verify a state of the flash memory cell after a programming pulse has been applied to the gate of the flash memory cell.

10. The method of claim 1 wherein programming a flash memory cell includes programming a multi-state flash memory cell holding one of four or more threshold voltages to an erased state or to one of three or more threshold voltages.

11. The method of claim 1 wherein:
programming a flash memory cell includes coupling a programming pulse to a gate of a selected floating gate transistor memory cell to induce charge to be added to a floating gate of the selected floating gate transistor memory cell to increase a threshold voltage of the selected floating gate transistor memory cell, the selected floating gate transistor memory cell including the gate, a drain, a source, and the floating gate; and
coupling a word-line voltage to the flash memory cell includes:
coupling a program verify voltage to the gate of the selected floating gate transistor memory cell, the drain and the source being coupled in series in a nandstring of a plurality of floating gate transistor memory cells in an array of floating gate transistor memory cells, each of the floating gate transistor memory cells other than the selected floating gate transistor memory cell being in a conductive state;
rendering conductive a drain select transistor coupled to the nandstring; and
rendering conductive a source select transistor coupled to the nandstring.

12. An article including a machine-accessible medium having associated information, wherein the information results in a machine performing:
programming a flash memory cell;
coupling a word-line voltage to the flash memory cell; and
sensing a state of the flash memory cell at a plurality of intervals to generate a plurality of data to indicate the state of the flash memory cell.

13. The article of claim 12 wherein the information results in a machine performing:
coupling a bit-line coupled to the flash memory cell to a sense capacitance at a first time to generate first data; and
coupling the bit-line to the sense capacitance at a second time to generate second data.

14. The article of claim 13 wherein the information results in a machine performing:
latching the first data in a first latch; and
latching the second data in a second latch.

15. The article of claim 13 wherein the information results in a machine performing:
coupling a pre-program verify voltage to a gate of the flash memory cell at the first time; and
coupling a program verify voltage to the gate of the flash memory cell at the second time, the program verify voltage being greater than the pre-program verify voltage to verify a state of the flash memory cell after a programming pulse has been applied to the gate of the flash memory cell.

16. The article of claim 12 wherein the information results in a machine performing:
coupling a bit-line coupled to the flash memory cell to a sense capacitance according to a first plurality of pulses to verify a programming of the flash memory cell; and
coupling the bit-line to the sense capacitance according to a second plurality of pulses to read a state of the flash memory cell, the second plurality of pulses having the same duration and occurring at the same intervals, respectively, as the first plurality of pulses such that the bit-line is coupled to the sense capacitance at the same intervals when a programming of the flash memory cell is being verified and when the flash memory cell is being read.

17. The article of claim 12 wherein the information results in a machine performing:
switching off a latch in a cache memory of a NAND flash memory;
initializing the latch while the latch is switched off;
coupling a read voltage to a gate of the flash memory cell in the NAND flash memory, the flash memory cell being coupled to a bit-line;
coupling the bit-line to an input of the latch while a voltage on the bit-line is changing due to the read voltage coupled to the flash memory cell and the latch is switched off; and
switching on the latch to latch data based on the voltage on the bit-line.

18. A method comprising:
switching off a latch in a cache memory of a NAND flash memory;
initializing the latch while the latch is switched off;
coupling a read voltage to a gate of a selected flash memory cell in the NAND flash memory, the selected flash memory cell being coupled to a bit-line;
coupling the bit-line to an input of the latch while a voltage on the bit-line is changing due to the read voltage coupled to the selected flash memory cell and the latch is switched off; and
switching on the latch to latch data based on the voltage on the bit-line.

19. The method of claim 18 wherein:
switching off a latch includes switching off each of a pair of inverters coupled to latch the data, each inverter having an output coupled to an input of the other inverter;
initializing the latch includes coupling the outputs of the inverters together through a transistor to reduce a potential difference between the outputs of the inverters;
coupling the bit-line includes switching on a bias transistor and a latch transistor in series between the bit-line and the inverters; and
switching on the latch includes switching on each of the inverters.

20. The method of claim 18, further comprising:
programming the selected flash memory cell; and
sensing a state of the selected flash memory cell at a plurality of intervals to generate a plurality of data to indicate a state of the selected flash memory cell.

21. The method of claim 20 wherein sensing a state of the selected flash memory cell includes:
sensing a first voltage on the bit-line at a first time; and
sensing a second voltage on the bit-line at a second time.

22. The method of claim 21, further comprising:
generating first data from the first voltage;
latching the first data in a first latch;
generating second data from the second voltage; and
latching the second data in a second latch.

23. The method of claim 18, further comprising:
coupling the bit-line to the input of the latch a plurality of times while the read voltage is coupled to the selected flash memory cell; and
switching on the latch to latch data based on the voltage on the bit-line each time the bit-line is coupled to the input of the latch to latch a plurality of data while the read voltage is coupled to the selected flash memory cell.

24. A system comprising:
a unidirectional antenna;
a display; and
an article including a machine-accessible medium having associated information, wherein the information results in a machine performing:
programming a flash memory cell;
coupling a word-line voltage to the flash memory cell; and
sensing a state of the flash memory cell at a plurality of intervals to generate a plurality of data to indicate the state of the flash memory cell.

25. The system of claim 24 wherein the information results in a machine performing:
coupling a bit-line coupled to the flash memory cell to a sense capacitance at a first time to generate first data; and
coupling the bit-line to the sense capacitance at a second time to generate second data.

26. The system of claim 24 wherein the information results in a machine performing:
coupling a pre-program verify voltage to a gate of the flash memory cell at a first time; and
coupling a program verify voltage to the gate of the flash memory cell at a second time, the program verify voltage being greater than the pre-program verify voltage to verify a state of the flash memory cell after a programming pulse has been applied to the gate of the flash memory cell.

27. The system of claim 24 wherein the information results in a machine performing:
coupling a bit-line coupled to the flash memory cell to a sense capacitance according to a first plurality of pulses to verify a programming of the flash memory cell; and
coupling the bit-line to the sense capacitance according to a second plurality of pulses to read a state of the flash memory cell, the second plurality of pulses having the same duration and occurring at the same intervals, respectively, as the first plurality of pulses such that the bit-line is coupled to the sense capacitance at the same intervals when a programming of the flash memory cell is being verified and when the flash memory cell is being read.

28. The system of claim 24, further comprising:
a transceiver coupled to the antenna;
an input device;
a non-volatile memory including the flash memory cell, the non-volatile memory being the machine-accessible medium; and
a central processor coupled to the transceiver, the display, the input device, and the non-volatile memory, the central processor including the machine.
